(19) United States
(12) Patent Application Publication
(10) Pub. No.: US 2013/0163182 A1
(43) Pub. Date: Jun. 27, 2013

(54) DRIVE BRACKET ASSEMBLY

(71) Applicants: XUE-JIAO GUO, Wuhan City (CN); RONG-RONG SONG, Wuhan City (CN); TAI-BAO WU, Wuhan City (CN)

(72) Inventors: XUE-JIAO GUO, Wuhan City (CN); RONG-RONG SONG, Wuhan City (CN); TAI-BAO WU, Wuhan City (CN)

(73) Assignees: HON HAI PRECISION INDUSTRY CO., LTD., Tu-Cheng (TW); HONG FU JIN PRECISION INDUSTRY (WuHan) CO., LTD., Wuhan City (CN)

(21) Appl. No.: 13/618,674

(22) Filed: Sep. 14, 2012

(30) Foreign Application Priority Data
Dec. 26, 2011 (CN) 201110440360.X

(51) Int. Cl. H05K 7/16; G06F 1/16

(52) U.S. Cl. 361/679.33; 312/223.2

(57) ABSTRACT

A drive bracket assembly includes a computer enclosure and a drive bracket. The computer enclosure includes a bottom wall and a front wall extending from the bottom wall. The front wall includes a first mounting panel. The first mounting panel defines a first positioning hole and a second positioning hole. The drive bracket includes a bottom plate and a positioning protrusion. The positioning protrusion is received in the first positioning hole to enable the bottom plate to be parallel to the bottom wall. The positioning protrusion is received in the second positioning hole to enable the bottom plate to keep an angle relative to the bottom wall.

### BACKGROUND

1. Technical Field

The present disclosure relates to drive bracket assemblies, particularly to a drive bracket assembly with a pivotable drive bracket.

2. Description of Related Art

In computers, a disk drive is attached in a drive bracket. Pivotable drive brackets have circular pivots on opposite sides. The computer provides circular holes in a front panel. The pivots can rotate in the holes to pivotably attach the disk drive to the computer enclosure. However, no locating components are available to maintain the bracket after the bracket is rotated, and therefore an operator must hold the drive bracket by hand while removing the disk drive.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a drive bracket assembly in accordance with an embodiment and a disk drive.

FIG. 2 is an isometric view of a drive bracket of FIG. 1.

FIG. 3 is an assembled view of the drive bracket assembly of FIG. 1.

FIG. 4 is an assembled view of FIG. 1 and shows the drive bracket in a first position.

FIG. 5 is an assembled view of FIG. 1 and shows the drive bracket in a second position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

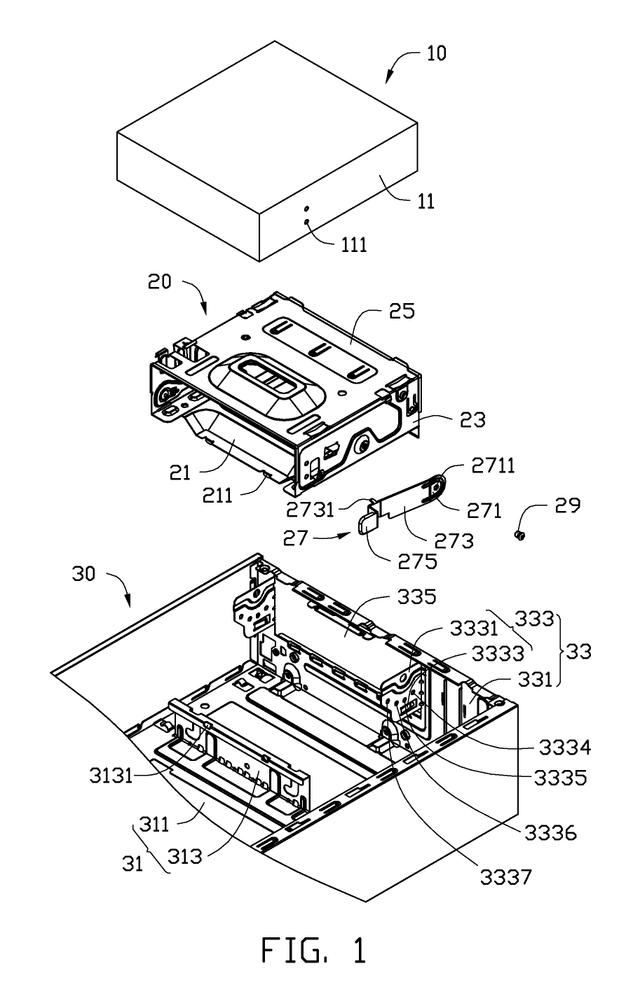

Referring to FIG. 1, a drive bracket assembly includes a drive bracket 20 and a computer enclosure 30. The drive bracket assembly is used for mounting a data storage device 10. The data storage device 10 includes two side panels 11. Each side panel 11 defines two securing holes 111.

The computer enclosure 30 includes a bottom wall 31 and a front wall 33. The bottom wall 31 includes a bottom wall body 311 and a support panel 313 perpendicularly extending from the bottom wall body 311. The front wall 33 includes a front wall body 331, perpendicularly extending from the bottom wall body 311, and mounting panels 333, perpendicularly extending from the front wall body 331. The front wall body 331 defines an opening 335 located between the two mounting panels 333. Each mounting panel 333 includes a panel body 3331 and a resilient tab 3333, extending from the panel body 3331 at an angle. The panel body further defines a pivot hole 3332, a first positioning hole 3334, a second positioning hole 3335, a third positioning hole 3336, and a fourth positioning hole 3337. The distances between the pivot hole 3332 and the positioning holes are substantially the same. The support panel 313 defines two positioning openings 3131.

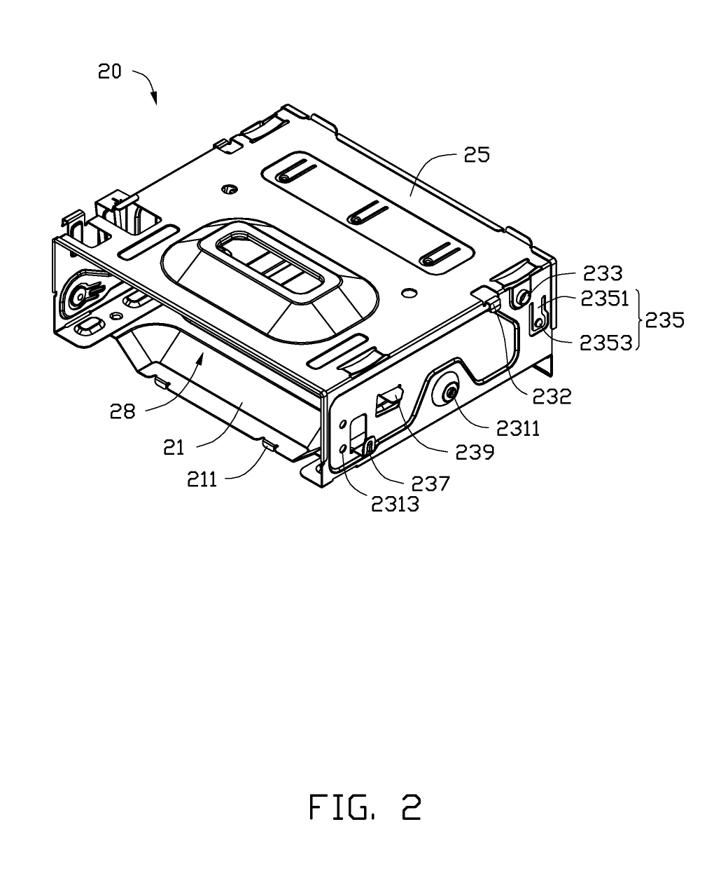

Referring to FIG. 2, the drive bracket 20 includes a bottom plate 21, two side plates 23 perpendicularly extending from the bottom plate 21, a top plate 25 connected between the two side plates 23, and a mounting tab 27. The bottom plate 21 includes two positioning portions 211 corresponding to the two positioning openings 3131. A receiving space, for receiving the data storage device 10, is defined in the drive bracket 20.

Each side plate 23 includes a side plate body 231, a resisting tab 232, a pivot post 233, and a positioning tab 235 extending from the side plate body 231. The positioning tab 235 includes a connecting arm 2351 connected to the side plate body 231 and a positioning protrusion 2353 extending from the connecting arm 2351. The resisting tab 232 is L-shaped. One of the side plate bodies 231 defines a first rotating hole 2311 and two through holes 2313. The side plate 23 further includes a first stopper tab 237 and a second stopper tab 239 extending from the side plate body 231. The mounting tab 27 includes a rotating portion 271, an extending portion 273 extending from the rotating portion 271, and a handling portion 275 extending from the extending portion 273. The extending portion 273 includes two securing posts 2731, corresponding to the securing holes 111 of the data storage device 10. The rotating portion 271 defines a second rotating hole 2711.

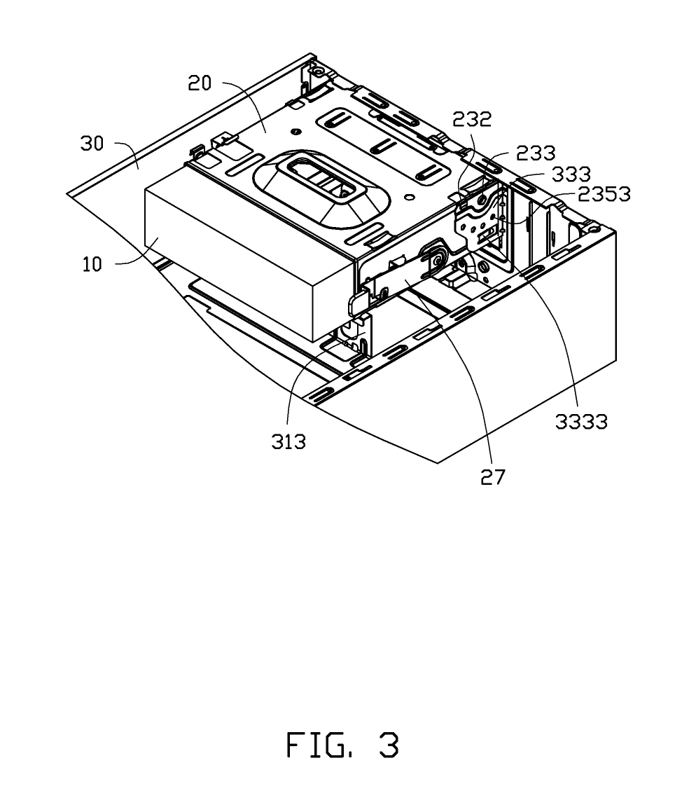

Referring to FIG. 3, in assembly, a pivot member 29 extends through the second rotating hole 2711 and the first rotating hole 2311 to pivotally mount the mounting tab 27 to the side plate 23. The two securing posts 2731 are received in the through holes 2313. Each pivot post 233 is received in the pivot hole 3332, of the mounting panel 333, to pivotally mount the drive bracket 20 to the mounting panel 333. The positioning protrusion 2353 is received in the first positioning hole 3334, to enable the bottom plate 21 to be parallel to the bottom wall 31 of the computer enclosure 30. At this time, the panel body 3331 of the mounting panel 333 is received between the side plate body 231 and the resisting tab 232. The bottom plate 21 of the drive bracket 20 is placed on the support panel 313 of the bottom wall 31. The positioning portion 211 is received in the positioning opening 3131. The receiving space 28 corresponds to the opening 335. The resilient tab 3333 elastically resists the side plate 23 of the drive bracket 20. The data storage device 10 is received in the receiving space 28 via the opening 335. The handling portion 275 is pulled outward to enable the securing posts 2731 to move away from the through holes 2313. The mounting tab 27 rotates along a first direction to enable the securing post 2731 to resist the side plate body 231. At this time, the extending portion 273 is deformed. The data storage device 10 is pushed inward until the securing holes 111 of the data storage device 10 are aligned with the through holes 2313. The mounting tab 27 rotates along a second direction, opposite to the first direction, to enable the securing posts 2731 to be aligned with the through holes 2313. The extending portion 273 is released to enable the securing posts 2731 to extend through the through hole 2313 and the securing holes 111, thereby securing the data storage device 10 to the drive bracket 20.

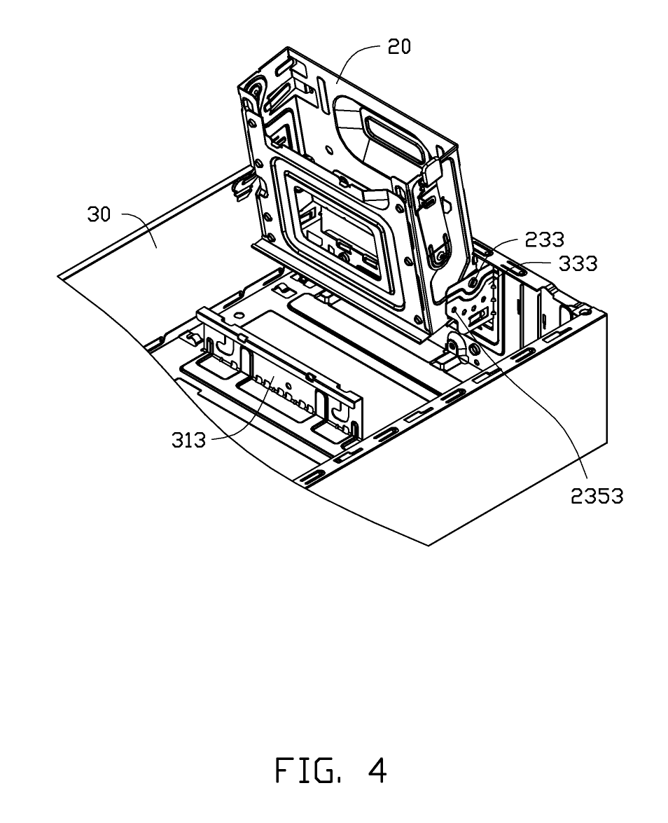

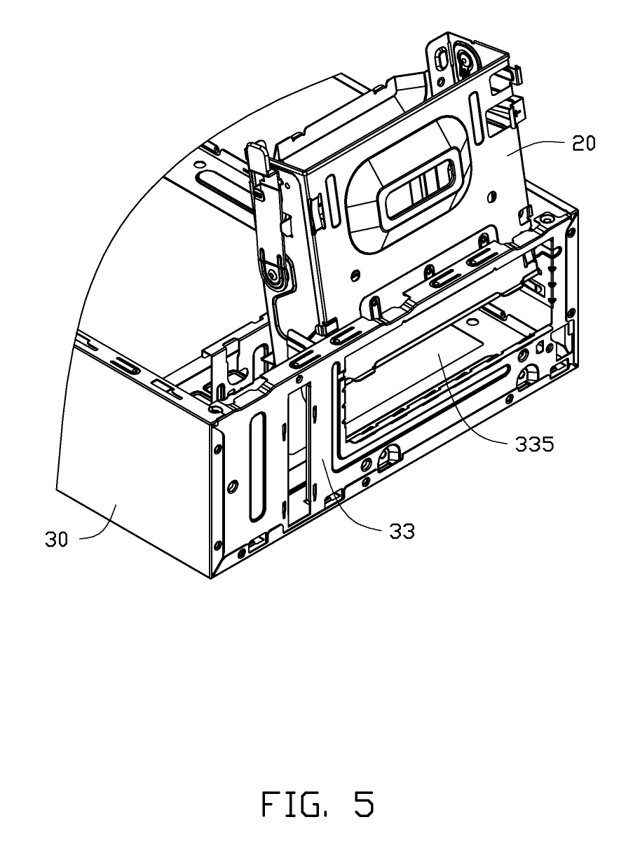

Referring to FIGS. 4 and 5, when the computer needs checking, there is no need to remove the drive bracket 20 from the computer enclosure 30. The drive bracket 20 can be rotated outward to enable the positioning protrusions 2353 to be positioned in one of the second positioning holes 3335, the third positioning holes 3336, and the fourth positioning holes 3337, thereby positioning the drive bracket at the different positions relative to the computer enclosure 30.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A drive bracket assembly comprising:
a computer enclosure, the computer enclosure comprises a bottom wall and a front wall, extending from the bottom wall; the front wall comprises a first mounting panel; the first mounting panel defines a first positioning hole and a second positioning hole; and
a drive bracket, the drive bracket comprises a bottom plate and a positioning protrusion; the positioning protrusion is received in the first positioning hole to enable the bottom plate to be parallel to the bottom wall; and the positioning protrusion is configured to be received in the second positioning hole to enable the bottom plate to keep an angle relative to the bottom wall.

2. The drive bracket assembly of claim 1, wherein the front wall is substantially perpendicular to the bottom wall; the front wall further comprises a front wall body; the first mounting panel extends from the front wall body; and the drive bracket is pivotally mounted to the first mounting panel.

3. The drive bracket assembly of claim 2, wherein the drive bracket further comprises a side plate extending from the bottom plate; the side plate is substantially perpendicular to the bottom plate; the side plate comprises a pivot post; the first mounting panel defines a pivot hole receiving the pivot post; and a distance between the pivot hole and the first positioning hole is substantially equal to a distance between the pivot hole and the second positioning hole.

4. The drive bracket assembly of claim 2, wherein the first mounting panel comprises a resilient tab resisting the drive bracket.

5. The drive bracket assembly of claim 1, wherein the drive bracket further comprises a side plate extending from the bottom plate and a mounting tab pivotally mounted to the side plate; the side plate is substantially perpendicular to the bottom plate; and the mounting tab comprises a securing post for engaging a data storage device in the drive bracket.

6. The drive bracket assembly of claim 5, wherein the mounting tab comprises a rotating portion pivotally mounted to the side plate, an extending portion extending from the rotating portion, and a handling portion extending from the extending portion; the securing post is connected to the extending portion; and the handling portion is configured to be operated to disengage the securing post from the data storage device.

7. The drive bracket assembly of claim 1, wherein the front wall is substantially perpendicular to the bottom wall; the front wall further comprises a front wall body and a second mounting panel extending from the front wall body; and the drive bracket is mounted between the first mounting panel and the second mounting panel.

8. The drive bracket assembly of claim 7, wherein the front wall body defines an opening corresponding to the drive bracket for receiving a data storage device, and the opening is located between the first mounting panel and the second mounting panel.

9. The drive bracket assembly of claim 1, wherein the bottom wall comprises a bottom wall body and a support panel extending from the bottom wall body; the support panel is substantially perpendicular to the bottom wall body; and the drive bracket is placed on the support panel.

10. The drive bracket assembly of claim 9, wherein the bottom plate comprises a positioning portion, and the support panel defines a positioning opening receiving the positioning portion.

11. A data storage device assembly comprising:
a computer enclosure, the computer enclosure comprises a bottom wall and a front wall, extending from the bottom wall; the front wall comprises two mounting panels; each mounting panel defines a first positioning hole and a second positioning hole;
a data storage device; and
a drive bracket pivotally mounted to the front wall, the drive bracket receiving the data storage device; the drive bracket comprises a positioning protrusion; the positioning protrusion is received in the first positioning hole in a first position; and the positioning protrusion is configured to be received in the second positioning hole in a second position when the drive bracket rotates.

12. The data storage device assembly of claim 11, wherein the front wall is substantially perpendicular to the bottom wall; the front wall comprises a front wall body; the two mounting panels extend from the front wall body; and the drive bracket pivotally mounted to the two mounting panels.

13. The data storage device assembly of claim 12, wherein the drive bracket comprises a bottom plate and a side plate extending from the bottom plate; the side plate is substantially perpendicular to the bottom plate; the side plate comprises a pivot post; each mounting panel defines a pivot hole receiving the pivot post; and a distance between the pivot hole and the first positioning hole is substantially equal to a distance between the pivot hole and the second positioning hole.

14. The data storage device assembly of claim 12, wherein one of the two mounting panels comprises a resilient tab resisting the drive bracket.

15. The data storage device assembly of claim 11, wherein the drive bracket comprises a bottom plate, a side plate extending from the bottom plate and a mounting tab pivotally mounted to the side plate; the side plate is substantially perpendicular to the bottom plate; the data storage device comprises a side panel defining a securing hole; and the mounting tab comprises a securing post for engaging in the securing hole.

16. The data storage device assembly of claim 15, wherein the mounting tab comprises a rotating portion pivotally mounted to the side plate, an extending portion extending from the rotating portion, and a handling portion extending from the extending portion; the securing post is connected to the extending portion; and the handling portion is configured to be operated to enable the securing post to disengage from the securing hole.

17. The data storage device assembly of claim 11, wherein the front wall is substantially perpendicular to the bottom wall; the front wall further comprises a front wall body; the drive bracket is mounted between the two mounting panels.

18. The data storage device assembly of claim 17, wherein the front wall body defines an opening corresponding to the drive bracket for receiving the data storage device, and the opening is located between the two mounting panels.

19. The data storage device assembly of claim 11, wherein the bottom wall comprises a bottom wall body and a support panel extending from the bottom wall body; the support panel is substantially perpendicular to the bottom wall body; and the drive bracket is placed on the support panel.

20. The data storage device assembly of claim 19, wherein the drive bracket comprises a positioning portion, and the support panel defines a positioning opening receiving the positioning portion.
